(19) United States
(12) Patent Application Publication
(10) Pub. No.: US 2022/0298635 A1
(43) Pub. Date: Sep. 22, 2022

(54) THERMAL ALD OF METAL THIN FILMS

(71) Applicant: WAYNE STATE UNIVERSITY, Detroit, MI (US)

(72) Inventors: Charles H. WINTER, Bloomfield Hills, MI (US); Anuththara Chalani Upeksha ABESINGHE ARACHCHIGE, Detroit, MI (US); Nyi Myat Khine LINN, Detroit, MI (US)

(21) Appl. No.: 17/203,054

(22) Filed: Mar. 16, 2021

(51) Int. Cl. C23C 16/455

(52) U.S. Cl. CPC C23C 16/45553; C23C 16/45527; C23C 16/18

(57) ABSTRACT

A method for depositing a metal-containing layer includes a deposition cycle having a step of contacting a surface of a substrate with a vapor of a metal-containing compound for a first predetermined pulse time to form a modified surface. The metal-containing compound is described by formula 1.2:

M(x)LₘGₙ (1.1),

wherein:
M is a metal;
M(x) is a metal in an oxidation state x that disproportionates at a temperature above 30° C.;
x is the oxidation state:
L is an anionic ligand;
G is a neutral ligand;
m is an integer (e.g., 1, 2, 3, 4 or 5) such that m is chosen to maintain charge neutrality of the compound having formula 1; and
n is 0, 1, 2, 3, 4, 5, or 6.
   The modified surface is contacted with a vapor of a first co-reactant (e.g., an activating compound) to form a metal-containing layer on the substrate.

### TECHNICAL FIELD

In at least one aspect, the present invention relates to forming titanium metal layers by atomic layer deposition at low temperatures.

### BACKGROUND

Titanium metal is a high-strength, low-density transition metal that has potential for future electronics and microelectronics. Moreover, titanium metal and/or alloys with other metals such as cobalt are already useful in microelectronics applications. For example, amorphous CoTiₓ (x=18-83%) alloys can be used as a barrier layer that can replace current W/Ti/TiN contact plugs and other liners in integrated circuits. CoTix is also useful as a Cu diffusion barrier. In this regard, the ALD of titanium and cobalt metal is required for deposition in high aspect ratio features. Currently, little is known about the ALD of titanium.

Accordingly, there is a need for an improved process for forming titanium and similar metal films for microelectronic applications.

### SUMMARY

In at least one aspect, a method for depositing a metal-containing layer is provided. The method including a deposition cycle having a step of contacting a surface of a substrate with a vapor of a metal-containing compound for a first predetermined pulse time to form a modified surface disposed over the substrate. The metal-containing compound is described by formulae 1:

M(x)LₘGₙ (1.1),

wherein:
M(x) is a metal in an oxidation state x that disproportionates at a temperature above 30° C.;
x is the oxidation state:
L is an anionic ligand;
G is a neutral ligand;
m is an integer (e.g., 1, 2, 3, 4 or 5) chosen to maintain charge neutrality of the compound having formula 1; and
n is 0, 1, 2, 3, 4, 5, or 6.
   The modified surface is contacted with a vapor of a first co-reactant (e.g., an activating compound) to form a metal-containing layer on the substrate. Characteristically, the metal-containing layer is a metallic layer, a metal nitride layer, or a metal oxide layer depending on the type of co-reactant.

In another aspect, a method for depositing a titanium metal-containing layer is provided. The method includes a deposition cycle that includes a step of contacting a surface of a substrate with a vapor of an organometallic compound that includes Ti(III) for a first predetermined pulse time to form a modified surface disposed over the substrate. The organometallic compound that includes Ti(III) is described by formulae 1.2:

Ti(III)L₃Gₙ (1.2),

wherein:
Ti(III) is a titanium atom in a +3 oxidation state;
L is an anionic ligand;
G is a neutral ligand; and
n is 0, 1, 2, or 3.
   The modified surface is contacted with a vapor of a first co-reactant (e.g., an activating compound) to form a titanium metal-containing layer on the substrate. Characteristically, the titanium-containing layer is a metallic layer, a metal nitride layer, or a metal oxide layer depending on the first co-reactant.

In another aspect, a method for depositing an alloy layer is provided. The method includes a step of contacting a surface of a substrate with a vapor of a first organometallic compound for a first predetermined pulse time to form a first modified surface disposed over the substrate. The first organometallic compound is described by formulae 1.1:

M(x)LₘGₙ (1.1),

wherein:
M(x) is a metal in an oxidation state x that disproportionates at a temperature above 30° C.;
x is the oxidation state. In a refinement, x is I (i.e., +1 oxidation state), II (i.e., +2 oxidation state), III (i.e., +3 oxidation state), IV (i.e., +4 oxidation state), or V (i.e., +5 oxidation state),
L is an anionic ligand;
G is a neutral ligand;
m is an integer (e.g., 1, 2, 3, 4, or 5) chosen to maintain charge neutrality of the compound having formula 1.1; and
n is 0, 1, 2, 3, 4, 5, or 6.
   The first modified surface is contacted with a vapor of a first co-reactant (e.g., a reducing agent and/or a Lewis base)) for a second predetermined pulse time to form a metal-containing layer. The metal-containing layer is contacted with a vapor of a second organometallic precursor for a third predetermined pulse time to form a second modified surface. Characteristically, the organometallic precursor includes a metal atom M′ that is not M. The second modified surface is contacted with a vapor of a second co-reactant (e.g., a reducing agent and/or a Lewis base) for a fourth predetermined pulse time to form an M′ metal-containing layer. Advantageously, the M and M′ layers mix under the deposition conditions to form the alloy and not just a superlattice of M and M′.

In another aspect, a method for depositing a titanium-containing alloy is provided. The method includes a step of contacting a surface of a substrate with a vapor of a first organometallic compound that includes Ti(III) for a first predetermined pulse time to form a first modified surface disposed over the substrate. The first organometallic compound is described by formulae 1.2:

Ti(III)L₃Gₙ (1.2),

wherein:
Ti(III) is a titanium atom in a +3 oxidation state;
L is an anionic ligand;
G is a neutral ligand;
n is 0, 1, 2, or 3; and
   The first modified surface is contacted with a vapor of a first co-reactant (e.g., a reducing agent and/or a Lewis base) for a second predetermined pulse time to form a titanium metal-containing layer. The titanium metal-containing layer is contacted with a vapor of an organometallic precursor for a third predetermined pulse time to form a second modified surface. Characteristically, the second organometallic precursor includes a metal atom M′ that is not titanium. The second modified surface is contacted with a vapor of a second co-reactant (e.g., a reducing agent and/or a Lewis base) for a fourth predetermined pulse time to form an M′ metal-containing layer, and therefore a titanium-containing alloy layer. Advantageously, the M′ and Ti layers mix under the deposition conditions to form the alloy and do not just form a superlattice of M′ and Ti.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

For a further understanding of the nature, objects, and advantages of the present disclosure, reference should be had to the following detailed description, read in conjunction with the following drawings, wherein like reference numerals denote like elements and wherein:

FIG. 1. Schematic illustration of an atomic layer deposition reactor for depositing metal films from Ti(III) precursors.

FIGS. 2A and 2B. Flowcharts showing formation of alloys.

FIG. 3A. Synthetic scheme for preparing Ti(^{iPr2}DAD)₃.

FIG. 3B. Thermogravimetric analysis for Ti(^{iPr2}DAD)₃.

FIG. 4A. Synthetic scheme for preparing Ti(III) enaminolate complexes.

FIG. 4B. X-Ray structure for Ti(^{iPr2}DAD)₃.

FIG. 4C. Thermogravimetric analysis for Ti(^{iPr2}DAD)₃.

FIG. 5A. Synthetic scheme of several Ti(III) β-diketonate complexes.

FIG. 5B. X-Ray crystal structure of Ti(acac)₃.

FIG. 5C. Thermogravimetric analysis for several Ti(III) β-diketonate complexes.

FIG. 6A. Synthetic scheme for the preparation of Ti(III) fluorinated β-diketonates.

FIG. 6B. Thermogravimetric analysis for Ti(III) fluorinated β-diketonates.

FIG. 7A. Synthetic scheme for a new class of Ti(III) fluorinated β-diketonates.

FIG. 7B. Thermogravimetric analysis for a new class of Ti(III) fluorinated β-diketonates.

FIG. 8A. Synthetic scheme for β-heteroarylalkenolate complexes.

FIG. 8B. Thermogravimetric analysis for β-heteroarylalkenolate complexes.

FIG. 9A. Synthetic scheme for a new class of Ti(BH₄)₃(DME).

FIG. 9B. Thermogravimetric analysis for a new class of Ti(BH₄)₃(DME).

FIG. 10A. Synthetic scheme for Ti(BH₄)₃(di-tert-butylethylenediamine)).

FIG. 10B. Thermogravimetric analysis for Ti(BH₄)₃(di-tert-butylethylene diamine)).

FIG. 11. Synthetic scheme Ti(BH₄)₃(di-tert-butylethylenediamine)).

### DETAILED DESCRIPTION

Reference will now be made in detail to presently preferred compositions, embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

Except in the examples, or where otherwise expressly indicated, all numerical quantities in this description indicating amounts of material or conditions of reaction and/or use are to be understood as modified by the word “about” in describing the broadest scope of the invention. Practice within the numerical limits stated is generally preferred. Also, unless expressly stated to the contrary: all R groups (e.g. Rᵢ where i is an integer) include hydrogen, alkyl, lower alkyl, C₁₋₆ fluorinated alkyl, C₁₋₆ perfluoroalkyl, C₆₋₁₀ aryl, C₂₋₁₀ heteroaryl, —NO₂, —NH₂, —N(R′R″), —N(R′R″R′″)⁺L⁻, Cl, F, Br, —CF₃, —CCl₃, —CN, —SO₃H, —PO₃H₂, —COOH, —CO₂R′, —COR′, —CHO, —OH, —OR′, —O⁻M⁺, —SO₃⁻M⁺, —PO₃⁻M⁺, —COO⁻M⁺, —CF₂H, —CF₂R′, —CFH₂, and —CFR′R″ where R′, R″ and R′″ are C₁₋₁₀ alkyl or C₆₋₁₈ aryl groups; single letters (e.g., “n” or “o”) are 1, 2, 3, 4, or 5; in the compounds disclosed herein a CH bond can be substituted with alkyl, lower alkyl, C₁₋₆ alkyl, C₁₋₆ fluorinated alkyl, C₁₋₆ perfluoroalkyl, C₆₋₁₀ aryl, C₂₋₁₀ heteroaryl, —NO₂, —NH₂, —N(R′R″), —N(R′R″R′″)⁺L⁻, Cl, F, Br, —CF₃, —CCl₃, —CN, —SO₃H, —PO₃H₂, —COOH, —CO₂R′, —COR′, —CHO, —OH, —OR′, —O⁻M⁺, —SO₃⁻M⁺, —PO₃⁻M⁺, —COO⁻M⁺, —CF₂H, —CF₂R′, —CFH₂, and —CFR′R″ where R′, R″ and R′″ are C₁₋₁₀ alkyl or C₆₋₁₈ aryl groups; percent, “parts of,” and ratio values are by weight; the term “polymer” includes “oligomer,” “copolymer,” “terpolymer,” and the like; molecular weights provided for any polymers refers to weight average molecular weight unless otherwise indicated; the description of a group or class of materials as suitable or preferred for a given purpose in connection with the invention implies that mixtures of any two or more of the members of the group or class are equally suitable or preferred; description of constituents in chemical terms refers to the constituents at the time of addition to any combination specified in the description, and does not necessarily preclude chemical interactions among the constituents of a mixture once mixed; the first definition of an acronym or other abbreviation applies to all subsequent uses herein of the same abbreviation and applies mutatis mutandis to normal grammatical variations of the initially defined abbreviation; and, unless expressly stated to the contrary, measurement of a property is determined by the same technique as previously or later referenced for the same property.

It must also be noted that, as used in the specification and the appended claims, the singular form “a,” “an,” and “the” comprise plural referents unless the context clearly indicates otherwise. For example, reference to a component in the singular is intended to comprise a plurality of components.

The term “C₁₋₆ alkyl” includes C₁ alkyl, C₂ alkyl, C₃ alkyl, C₄ alkyl, C₅ alkyl, or C₆ alkyl. Therefore, C₁₋₆ alkyl includes C₁₋₂ alkyl, C₁₋₃ alkyl, C₁₋₄ alkyl, C₁₋₅ alkyl as subranges that are also disclosed. Examples of C₁₋₆ alkyl include, but are not limited to, methyl, ethyl, n-propyl, isopropyl, n-butyl, isobutyl, t-butyl, n-pentyl, iso-pentyl, and hexyl.

As used herein, the term “about” means that the amount or value in question may be the specific value designated or some other value in its neighborhood. Generally, the term “about” denoting a certain value is intended to denote a range within +/−5% of the value. As one example, the phrase “about 100” denotes a range of 100+/−5, i.e., the range from 95 to 105. Generally, when the term “about” is used, it can be expected that similar results or effects according to the invention can be obtained within a range of +/−5% of the indicated value.

As used herein, the term “and/or” means that either all or only one of the elements of a said group may be present. For example, “A and/or B” shall mean “only A, or only B, or both A and B”. In the case a “only A”, the term also covers the possibility that B is absent, i.e., “only A, but not B”.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

The term “comprising” is synonymous with “including,” “having,” “containing,” or “characterized by.” These terms are inclusive and open-ended and do not exclude additional, unrecited elements or method steps.

The phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

The phrase “composed of” means “including” or “consisting of.” Typically, this phrase is used to denote that an object is formed from a material.

With respect to the terms “comprising,” “consisting of,” and “consisting essentially of,” where one of these three terms is used herein, the presently disclosed and claimed subject matter can include the use of either of the other two terms.

The term “one or more” means “at least one” and the term “at least one” means “one or more.” The terms “one or more” and “at least one” include “plurality” as a subset.

The term “substantially,” “generally,” or “about” may be used herein to describe disclosed or claimed embodiments. The term “substantially” may modify a value or relative characteristic disclosed or claimed in the present disclosure. In such instances, “substantially” may signify that the value or relative characteristic it modifies is within ±0%, 0.1%, 0.5%, 1%, 2%, 3%, 4%, 5% or 10% of the value or relative characteristic.

It should also be appreciated that integer ranges explicitly include all intervening integers. For example, the integer range 1-10 explicitly includes 1, 2, 3, 4, 5, 6, 7, 8, 9, and 10. Similarly, the range 1 to 100 includes 1, 2, 3, 4 . . . 97, 98, 99, 100. Similarly, when any range is called for, intervening numbers that are increments of the difference between the upper limit and the lower limit divided by 10 can be taken as alternative upper or lower limits. For example, if the range is 1.1. to 2.1 the following numbers 1.2, 1.3, 1.4, 1.5, 1.6, 1.7, 1.8, 1.9, and 2.0 can be selected as lower or upper limits.

In the examples set forth herein, concentrations, temperature, and reaction conditions (e.g., pressure, pH, flow rates, etc.) can be practiced with plus or minus 50 percent of the values indicated rounded to or truncated to two significant figures of the value provided in the examples. In a refinement, concentrations, temperature, and reaction conditions (e.g., pressure, pH, flow rates, etc.) can be practiced with plus or minus 30 percent of the values indicated rounded to or truncated to two significant figures of the value provided in the examples. In another refinement, concentrations, temperature, and reaction conditions (e.g., pressure, pH, flow rates, etc.) can be practiced with plus or minus 10 percent of the values indicated rounded to or truncated to two significant figures of the value provided in the examples.

For all compounds expressed as an empirical chemical formula with a plurality of letters and numeric subscripts (e.g., CH₂O), values of the subscripts can be plus or minus 50 percent of the values indicated rounded to or truncated to two significant figures. For example, if CH₂O is indicated, a compound of formula C_{(0.8-1.2)}H_{(1.6-2.4)}O_{(0.8-1.2)}. In a refinement, values of the subscripts can be plus or minus 30 percent of the values indicated rounded to or truncated to two significant figures. In still another refinement, values of the subscripts can be plus or minus 20 percent of the values indicated rounded to or truncated to two significant figures.

The term “metal” as used herein means an alkali metal, an alkaline earth metal, a transition metal, a lanthanide, an actinide, or a post-transition metal. The terms “metal” and “metal atom” are interchangeable.

The term “alkali metal” means lithium, sodium, potassium, rubidium, cesium, and francium.

The “alkaline earth metal” means chemical elements in group 2 of the periodic table. The alkaline earth metals include beryllium, magnesium, calcium, strontium, barium, and radium.

The term “transition metal” means an element whose atom has a partially filled d sub-shell, or which can give rise to cations with an incomplete d sub-shell. Examples of transition metals includes scandium, titanium, vanadium, chromium, manganese, iron, cobalt, nickel, copper, yttrium, zirconium, niobium, molybdenum, technetium, ruthenium, rhodium, palladium, silver, hafnium, tantalum, tungsten, rhenium, osmium, iridium, platinum, and gold.

The term “lanthanide” or lanthanoid series of chemical elements” means an element with atomic numbers 57-71. The lanthanides metals include lanthanum, cerium, praseodymium, samarium, europium, gadolinium neodymium, promethium, terbium, dysprosium, holmium, erbium, thulium, ytterbium, or lutetium.

The term “actinide” or “actinide series of chemical elements” means chemical elements with atomic numbers from 89 to 103. Examples of actinides include actinium, thorium, protactinium, uranium, neptunium, and plutonium.

The term “post-transition metal” means gallium, indium, tin, thallium, lead, bismuth, zinc, cadmium, mercury, aluminum, germanium, antimony, or polonium.

The term “metallic layer” means a layer that includes metal atoms in the zero oxidation state. In refinements, the metallic layer includes at least 50 mole percent, 60 mole percent, 70 mole percent, 80 mole percent, or 50 mole percent metal atoms in the zero oxidation state. Sometimes “metallic layer” is referred to as “metal layer.”

The term “metal-containing layer refers to any layer that includes a metal atom in any oxidation state. Examples of metal-containing layers include metallic layers, metal nitride layers, and metal oxide layers.

As used herein the terms “layer” and “film” are interchangeable.

Throughout this application, where publications are referenced, the disclosures of these publications in their entireties are hereby incorporated by reference into this application to more fully describe the state of the art to which this invention pertains.

Abbreviations:

“acac” means acetylacetonate.

“ALD” means atomic layer deposition.

“Cy” means cyclohexyl.

“DAD” means diazabutadiene.

“iPr” means isopropyl.

“Nacac” means β-ketoiminate.

“TEEDA” means N,N,N′,N′-tetraethylethylenediamine.

“thd” means 2,2,6,6-tetramethyl-3,5-heptanedionate.

“tta” means 2-thienoyltrifluoroacetonate.

In an embodiment of the present embodiment, a method for depositing a titanium metal-containing layer (e.g., a thin film) on a surface of a substrate is provided. Typically, the method is an ALD method. The method includes a deposition cycle that can be repeated a plurality of times to build up the thickness of a metal-containing layer on a substrate to a predetermined thickness. In this context, the substrate can be the base substrate (i.e., uncoated) or a base substrate having one or more layers deposited thereon (e.g., from previous ALD steps). Characteristically, each deposition cycle comprises a step (step a) of contacting a substrate with a vapor of an organometallic compound described by formulae 1.1 or oligomers thereof at a first predetermined temperature:

M(x)LₘGₙ (1.1),

wherein:
M(x) is a metal in an oxidation state x that disproportionates at temperature above 30° C. (M is the metal atom);
x is the oxidation state. In a refinement, x is I (i.e., +1 oxidation state), II (i.e., +2 oxidation state), III (i.e., +3 oxidation state), IV (i.e., +4 oxidation state), or V (i.e., +5 oxidation state),
L is an anionic ligand;
G is a neutral ligand;
m is an integer (e.g., 1, 2, 3, 4 or 5) such that m is chosen to maintain charge neutrality of the compound having formula 1;
n is 0, 1, 2, 3, 4, 5, or 6; and
   In a refinement, M(x) is a metal in an oxidation state that disproportionates (when included in compound 1.1) at temperature above, in increasing order of preferences, 30° C., 50° C., 70° C., 90° C., 100° C., or 120° C. In a further refinement, M(x) is a metal in an oxidation state that disproportionates (when included in compound 1.1) at temperature below, in increasing order of preferences, 300° C., 250° C., 220° C., 200° C., 190° C., or 180° C. In a refinement, M(x) is Ti(III), Zr(II), Zr(III), Hf(II), Hf(III), V(II), V(III), V(IV), Nb(II), Nb(III), Nb(IV), Ta(II), Ta(III), Ta(IV), Cr(II), Cr(III), Cr(IV), Cr(V), Mo(II), Mo(III), Mo(IV), Mo(V), W(II), W(III), W(IV), or W(V). In a particularly useful refinement, M(x) is Ti(III).

In the next reaction step (step b) of the deposition cycle, the modified surface is contacted with a vapor of a first co-reactant for a second predetermined pulse time to form the metal-containing layer disposed over the surface of the substrate (step b). Depending on the first co-reactant as set forth below, the metal-containing layer can be a metallic layer (i.e., metal atoms in a zero oxidation state), a nitride layer, an oxide layer, or combinations thereof. Typically, a monolayer of the metal-containing layer is formed during each deposition cycle.

In a variation, a method for depositing a titanium metal-containing layer is provided. The method includes a deposition cycle that includes a step of contacting a surface of a substrate with a vapor of an organometallic compound that includes Ti(III) for a first predetermined pulse time to form a modified surface disposed over the substrate. The organometallic compound that includes Ti(III) is described by formulae 1.2:

Ti(III)L₃Gₙ (1.2),

wherein:
Ti(III) is a titanium atom in a +3 oxidation state;
L is an anionic ligand;
G is a neutral ligand; and
n is 0, 1, 2, or 3.
   The modified surface is contacted with a vapor of a first co-reactant (e.g., an activating compound) to form a titanium metal-containing layer on the substrate. Characteristically, the titanium-containing layer is a metallic layer, a metal nitride layer, or a metal oxide layer depending on the first co-reactant as set forth below in more detail.

Although the present embodiment is not limited by any particular theory of operation, it is believed that the metal layer is formed from a disproportionation reaction. For the organometallic compound having formula 1.2, this disproportionation is depicted below:

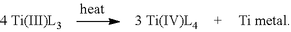

Presumably, Ti(IV)L₄ is volatile and thermally stable and is swept from the film growth ambient by the carrier gas. It is believed that T(II) can be formed as an immediate precursor to the titanium metal (e.g., titanium in the zero oxidation state).

Many compounds depicted by formula 1.1 and the compound of formula 1.2 can have a plurality of neutral ligands G. For a given compound, these neutral ligands G can be the same or different. Examples of neutral ligands G are well known. In a refinement, G is a pi donor ligand, a pi acceptor ligand, a Lewis base, or the like. For example, G can be carbon monoxide, carbon dioxide, water, ammonia, phosphine, pyridine, acetonitrile, ethylenediamine, 2,2′-bipyridine, 1,10-phenanthroline, triphenylphosphine, alkenes, benzene, 1,2-bis(diphenylphosphino)ethane, 1,1-Bis(diphenylphosphino)methane (dppm) diethylenetriamine (dien), pyrazine, phosphorus trifluoride, pi ligands, and the like.

It should also be appreciated that a variety of different ligands may be used for anionic ligand L. Many compounds depicted by formula 1.1 can have a plurality of anionic ligands L. For a given compound, these anionic ligands L can be the same or different. Significantly, L is a ligand that should impart sufficient volatility to the compounds having formulas 1.1 and 1.2 to be used in ALD or CVD processes. In a variation, L is a bidentate, monoanionic ligand. In some variations, L is an anionic ligand selected from the group consisting of tetrahydroborate, dialkyl amide ligands, enaminolate ligands, β diketonate ligands, β-heteroarylalkenolate ligands, and combinations thereof.

In a variation, at least one, 1 to m of the L are described by formula 2:

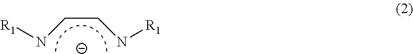

wherein R₁ is C₁₋₆ alkyl, C₁₋₆ fluorinated alkyl, or C₁₋₆ perfluoroalkyl. In a refinement, R₁ is C₁₋₃ alkyl, C₁₋₃ fluorinated alkyl, or C₁₋₃ perfluoroalkyl.

In a further refinement, 1 to m of the L are described by formula 3:

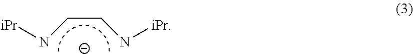

In a variation, 1 to m of the L are described by formula 4:

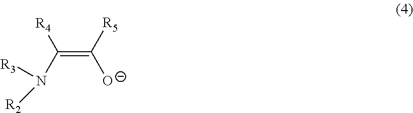

wherein R₂, R₃, R₄, and R₅ are each independently H, C₁₋₆ alkyl, C₁₋₆ fluorinated alkyl, C₆₋₁₂ aryl, C₂₋₆ heteroaryl, C₅₋₁₂ cycloalkyl, C₂₋₆ heterocycloalkyl, or C₁₋₆ perfluoroalkyl. In a refinement, R₂, R₃, R₄, and R₅ are each independently H, C₁₋₃ alkyl, C₁₋₃ fluorinated alkyl, or C₁₋₃ perfluoroalkyl. In another refinement, R₂ and R₃ are bonded together to form a C₅₋₇ heterocycloalkyl.

In a refinement, 1 to m of the L are described by formula 5, 6, and 7:

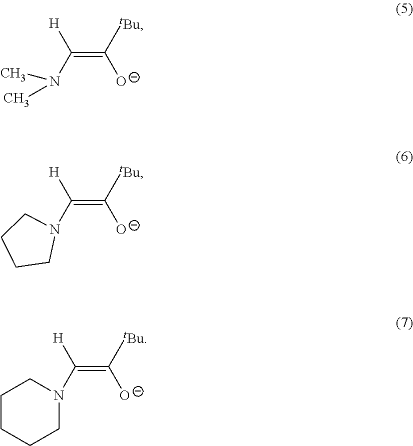

In another variation, 1 to m of the L are described by formula 8:

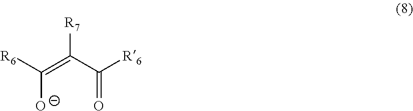

wherein R₆, R′₆, R₇ are each independently, H, C₁₋₆ alkyl, C₁₋₆ fluorinated alkyl, C₆₋₁₂ aryl, C₂₋₆ heteroaryl, C₅₋₁₂ cycloalkyl, C₂₋₆ heterocycloalkyl, or C₁₋₆ perfluoroalkyl. In a refinement, R₆, R₇ are each independently, H, C₁₋₃ alkyl, C₁₋₃ fluorinated alkyl, or C₁₋₃ perfluoroalkyl.

In a refinement, 1 to m of the L are described by formula 9, 10, 11, or 12:

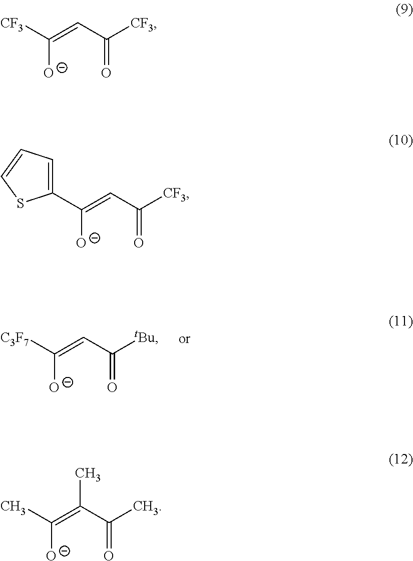

In another variation, 1 to m of the L are described by formula 13:

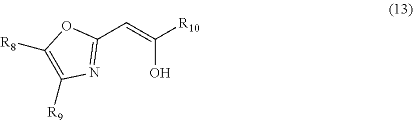

R₈, R₉, R₁₀ are each independently H, C₁₋₆ alkyl, C₁₋₆ fluorinated alkyl, C₆₋₁₂ aryl, C₂₋₆ heteroaryl, C₅₋₁₂ cycloalkyl, C₂₋₆ heterocycloalkyl, or C₁₋₆ perfluoroalkyl. In a refinement, R₇, R₈ are each independently, H, C₁₋₃ alkyl, C₁₋₃ fluorinated alkyl, or C₁₋₃ perfluoroalkyl.

In one variation, the metal-containing layer is a metallic layer (i.e., includes metal atoms M in the zero oxidation state). In a refinement, the first co-reactant is a reducing agent. Examples of reducing agents include, but are not limited to, molecular hydrogen, atomic hydrogen, silane, disilane, organosilanes, compounds containing Si—H bonds, germane, organogermanes, compounds containing Ge—H bonds, stannane, compounds containing Sn—H bonds, other metal hydride compounds, formic acid, glyoxalic acid, oxalic acid, other carboxylic acids, diborane, compounds containing B—H bonds, hydrazine, carbon-substituted hydrazines, formalin, formaldehyde, organic alcohols, organoaluminum compounds, organozinc compounds, and plasma-activated versions thereof. In another refinement, the first co-reactant for forming a metallic layer can be a Lewis base, and in particular, a neutral Lewis base. Examples of useful Lewis bases are secondary and tertiary amines as set forth below:

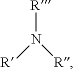

R′, R″ are C₁₋₆ alkyl and R′″ is H or C₁₋₆ alkyl. In a refinement, the Lewis base is selected from the group consisting of dimethylamine, diethyl amine, di-n-propyl amine, di-iso-propyl amine, and combinations thereof. In another refinement, the Lewis base is selected from the group consisting of CO, R₁₁NC (isonitriles), phosphines P(R₁₂)₃, and P(OR₁₃)₃ where R₁₁, R₁₂, and R₁₃ are each independently H, C₁₋₆ alkyl or C₆₋₁₂ aryl. In another refinement, the a first co-reactant is plasma H₂.

Characteristically, when the metal-containing layer is a metallic layer (i.e., includes metal atoms) in the zero oxidation state, the metal atoms in the zero oxidation state are present in an amount greater than 80 mole percent. In a refinement, the metal-containing layer (e.g., Ti) includes the metal atom in a zero oxidation state in an amount greater than 90 mole percent and metastable metal nitrides in an amount less than 10 mole percent.

In another variation, the metal-containing layer is a nitride layer, with the first co-reactant being a nitrogen-containing agent. Examples of nitrogen-containing agents include, but are not limited to, ammonia, hydrazine, C₁₋₆ alkyl-substituted hydrazines, and plasma activated versions thereof In another variation, the first co-reactant can be a C₁₋₆ primary amine having the following formula:

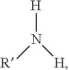

R′ is C₁₋₆ alkyl. In a refinement, the first co-reactant is selected from the group consisting of ammonia, methylamine, ethylamine, n-propyl amine, isopropyl amine, n-butyl amine, sec-butyl amine, isobutyl amine, tent-butyl amine, and combinations thereof.

In still another variation, the metal containing-layer is an oxide layer, with the first co-reactant being an oxidizing agent. Examples of oxidizing agents include, but are not limited to, water, ozone, molecular oxygen, atomic oxygen, organic alcohols, hydrogen peroxide, organic hydroperoxides, organic peroxides, nitrous oxide, and plasma-activated versions of thereof.

In a variation, the substrate is an electrically conductive substrate. In a refinement, such an electrically conductive substrate has an electrical resistivity that is less than about, in increasing order of preference 1×10⁻² ohm-m, 1×10⁻³ ohm-m, 1×10⁻⁴ ohm-m, 1×10⁻⁵ ohm-m, 1×10⁻⁶ ohm-m, 1×10⁻⁷ ohm-m. Most resistivities are greater than about 1×10⁻⁹ ohm-m. In a refinement, the electrically conductive substrate includes one or more surfaces composed of silicon, titanium nitride, tantalum nitride, or a metal. In a further refinement, the electrically conductive substrate includes one or more surfaces composed of copper or ruthenium. Examples of useful electrically conductive substrates include, but are not limited to, silicon (with the native oxide removed), titanium nitride coated substrates, tantalum nitride coated substrate, metal-coated base substrates, metal substrates, and silicon-coated substrates. Advantageously, certain metal-containing layers (e.g., a titanium metal-containing layer) grow selectively on surfaces of one or more electrically conductive films. In a refinement, the electrically conductive substrate includes one or more electrically conductive films disposed over a base substrate.

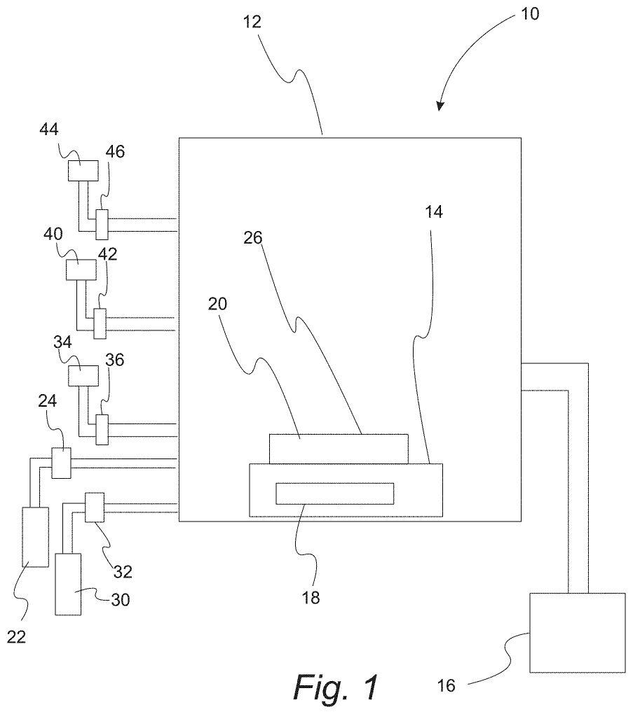

Referring to FIG. 1, ALD deposition system 10 includes a reaction chamber 12, substrate holder 14, and vacuum pump 16. Typically, the substrate is heated via heater 18 to a first predetermined temperature. The method has a deposition cycle that is repeated a plurality of times in order to build up the thickness of a titanium metal layer on substrate 20 to a predetermined thickness. Each deposition cycle comprises a step (step a) of contacting substrate 20 with a vapor of an organometallic compound described by formulae 1.1 or 1.2 or oligomers thereof.

Still referring to FIG. 1, the vapor of the organometallic compound described by formula 1.1 or 1.2 is introduced from precursor source 22 into the reaction chamber 12 for a first predetermined pulse time. In a variation, the compound from precursor source 22 is introduced into chamber 12 by direct liquid injection. The first predetermined pulse time should be sufficiently long that available binding sites on the substrate surface (coated with metal layers or uncoated) are saturated (i.e., metal-containing compound attached). Typically, the first predetermined pulse time is from 1 second to 20 seconds. The first predetermined pulse time is controlled via control valve 24. At least a portion of the vapor of the organometallic compound described by formula 1.1 or 1.2 modifies (e.g., adsorbs or reacts with) substrate surface 26 to form the first modified surface. In a refinement, the reaction chamber 12 is then purged with an inert gas for a first purge time. The inert gas is provided from purge gas source 30 and controlled by control valve 32. The first purge time is sufficient to remove the metal-containing compound from the reaction chamber 12 and is typically from 0.5 seconds to 2 minutes. Alternatively, the purging can be replaced with or supplemented by a pumping step.

In the next reaction step (step b) of the deposition cycle, the modified surface is contacted with a vapor of the first co-reactant. The first co-reactant can be provided from first co-reactant source 34, which is controlled by control valve 36. In a refinement, the reaction chamber 12 is then purged with an inert gas for a second purge time as set forth above. The second purge time is sufficient to remove the metal-containing compound from the reaction chamber 12 and is typically from 0.5 seconds to 2 minutes. As set forth above, this purging step can be replaced by or supplemented with a pumping step.

During each deposition cycle, the substrate temperature is typically maintained at a first predetermined temperature for steps a) and b). In a refinement, the first predetermined temperature is between 200 to 350° C. In a further refinement, steps a) and b) are performed at a first predetermined pressure of about 0.1 millitorrs to 100 Torr.

In another variation, steps a) and b) are repeated a plurality of times to form a metallic coating (e.g., titanium metal coating). For example, the deposition cycle can be repeated 1 to 5000 times. The desired metallic coating thickness depends on the number of deposition cycles. Therefore, in a refinement, the deposition cycle is repeated a plurality of times to form a predetermined thickness of the metallic coating. In a further refinement, the deposition cycle is repeated a plurality of times to form a metallic coating having a thickness from about 5 nanometers to about 200 nanometers. In still another refinement, the deposition cycle is repeated a plurality of times to form a metallic coating having a thickness from about 5 nanometers to about 300 nanometers. In yet another refinement, the deposition cycle is repeated a plurality of times to form a metallic coating having a thickness from about 5 nanometers to about 100 nanometers.

During film formation by the methods set forth above, the substrate temperature will be at a temperature suitable to the properties of the chemical precursor(s) and film to be formed. In a refinement of the method, the substrate is set to a temperature from about 0 to 1000° C. In another refinement of the method, the substrate has a temperature from about 150 to 450° C. In still another refinement of the method, the substrate has a temperature from about 200 to 350° C. In another refinement of the method, the substrate has a temperature from about 200 to 300° C.

Similarly, the pressure during film formation is set at a value suitable to the properties of the chemical precursors and film to be formed. In one refinement, the pressure is from about 1×10⁻⁶ Torr to about 760 Torr. In another refinement, the pressure is from about 0.1 millitorrs to about 100 Torr. In another refinement, the pressure is from about 0.1 millitorrs to about 100 Torr. In still another refinement, the pressure is from about 1 to about 10 millitorr. In yet another refinement, the pressure is from about 1 to 20 millitorr.

In a variation, the method further includes a step of annealing the metallic coating at a second predetermined temperature for a sufficient time that the metal-containing film includes the titanium metal atom in the zero oxidation state in an amount greater than 98 mole percent. Annealing can occur after each deposition step or after the deposition has been repeated a plurality of times to form the metallic coating. Characteristically, the second predetermined temperature is greater than the first predetermined temperature. In a refinement, the second predetermined temperature is greater than in increasing order of preference, 300° C., 310° C., 325° C., or 330° C. Typically, the second predetermined temperature is less than about 400° C.

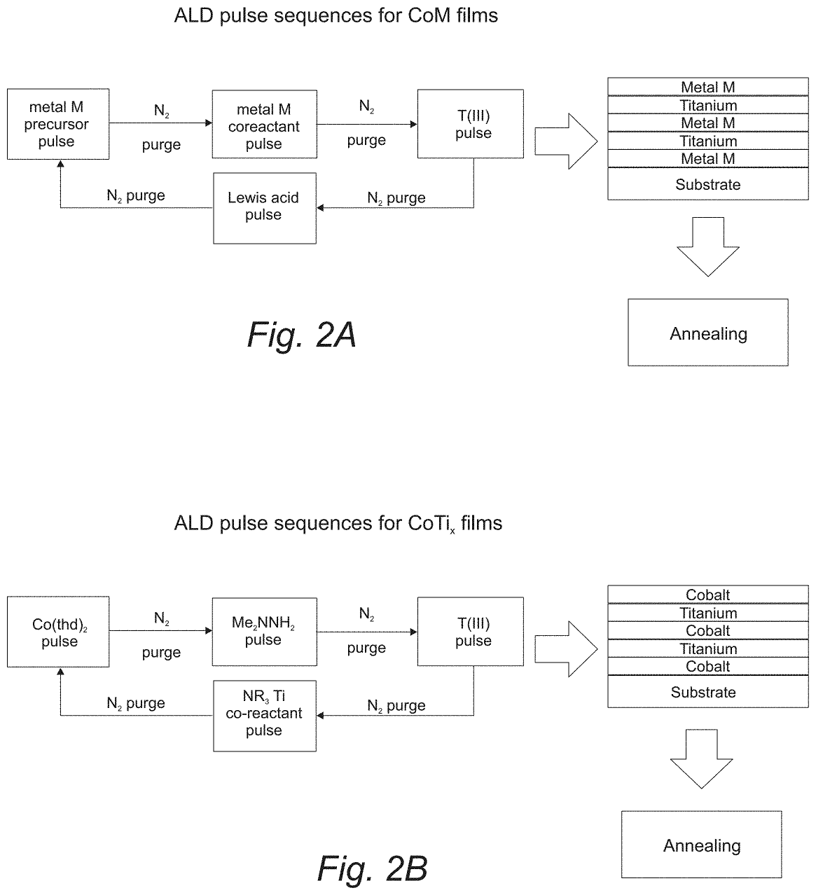

Referring to FIGS. 2A and 2B, a flowchart showing the formation of an alloy of metals M and M′ is provided. The alloy can be represented by MM′_{y} where y is 0.8 to 1.2. FIG. 2A provides the general scheme, while FIG. 2B provides a specific example for CoTi_{y}. In this variation, the deposition cycle includes a step depositing a layer of a metal M′ that is different than M. In a refinement, the metal M′ is a transition metal. Particularly useful transition metals include chromium, iron, silver, palladium, platinum, rhodium, iridium, cobalt, ruthenium, manganese, nickel, zinc, and copper. As shown in FIGS. 2A and 2B, each deposition cycle includes a step of contacting a surface of a substrate with a vapor of a first organometallic compound (e.g., Ti(III)-containing compound) for a first predetermined pulse time to form a modified surface disposed over the substrate as set forth above (step a). Characteristically, the a first organometallic compound is described by formulae 1.1 (or formula 1.2) as set forth above:

M(x)LₘGₙ (1.1),

wherein:
M(x) is a metal in an oxidation state x that disproportionates at temperature above 30° C.;
x is the oxidation state. In a refinement, x is I (i.e., +1 oxidation state), II (i.e., +2 oxidation state), III (i.e., +3 oxidation state), IV (i.e., +4 oxidation state), or V (i.e., +5 oxidation state),
L is an anionic ligand;
G is a neutral ligand;
m is an integer (e.g., 1, 2, 3, 4 or 5) such that m is chosen to maintain charge neutrality of the compound having formula 1;
n is 0, 1, 2, 3, 4, 5, or 6.
   In a refinement, M(x) is a metal in an oxidation state that disproportionates (when included in compound 1.1) at temperature above, in increasing order of preferences, 30° C., 50° C., 70° C., 90° C., 100° C., or 120° C. In a further refinement, M(x) is a metal in an oxidation state that disproportionates (when included in compound 1.1) at temperature below, in increasing order of preferences, 300° C., 250° C., 220° C., 200° C., 190° C., or 180° C. In a refinement, M(x) is Ti(III), Zr(II), Zr(III), Hf(II), Hf(III), V(II), V(III), V(IV), Nb(II), Nb(III), Nb(IV), Ta(II), Ta(III), Ta(IV), Cr(II), Cr(III), Cr(IV), Cr(V), Mo(II), Mo(III), Mo(IV), Mo(V), W(II), W(III), W(IV), W(V). In a particularly useful refinement, M(x) is Ti(III). In this context, the substrate can be the base substrate (i.e., uncoated) or a base substrate having one or more layers deposited thereon (e.g., from previous ALD steps). Details of the components for formula 1. (e.g., L and G) are the same as set forth above.

The first modified surface is contacted with a vapor of a first reactant for a second predetermined pulse time to form a metal-containing layer on the substrate (step b). Typically, the first co-reactant is a reactant suitable to form a metallic layer. Each deposition also includes a step of contacting the metal-containing layer with the vapor of a second organometallic compound that includes a metal M′ for a third predetermined pulse time to form a second modified surface (step c). The second modified surface is then contacted with the vapor of a second co-reactant for metal M′ (e.g., a Lewis base and/or a reductant) for a fourth pulse time to form a layer of metal M′ (step d). Typically, the second co-reactant is a reactant suitable to form a metallic layer. Examples of the second co-reactant include the reducing agents and Lewis bases as set forth above for the first co-reactant. The layer of metal M′ includes atoms of metal M′ in the zero oxidation state, and therefore, an alloy layer is formed. The bilayer of the metal M and metal M′ tend to intermix at the temperatures during the deposition.

Typically, the second organometallic compound has sufficient volatility for the ALD process. For example, the second organometallic compound (i.e., the metal M′ precursor) can be described by formula 13:

M′L′ₒGₚ (13)

wherein:
o is 1 to 8;
p is 1 to 8;
M′ is a metal, and in particular a transition metal that is not M of formula 1.1;
L′ is a ligand. A variety of different ligands may be used for L′. For example, L′ can be a two electron ligand, a multidentate ligand (e.g., a bidentate ligand), charged ligand (e.g., −1 charged), a neutral ligand, and combinations thereof. Examples for L′ and G are the same as set forth above for L and G.

In a refinement of the present embodiment, M′ is a transition metal in the 0 to +6 oxidation state. In a further refinement, M′ is a transition metal in the +1 to +6 oxidation state. In still a further refinement, M′ is a transition metal in the +2 oxidation state. Examples of useful metals for M′ include, but are not limited to, silver, palladium, platinum, rhodium, iridium, cobalt, ruthenium, manganese, nickel, and copper. In a refinement, M is Co, Cr, Mn, Fe, Zn, or Ni.

Referring again to FIG. 1, the method for forming an alloy includes steps a and b as set forth above. In particular, the vapor of the organometallic compound described by formula 1.1 or 1.2 is introduced from precursor source 22 into the reaction chamber 12 for a first predetermined pulse time. In a variation, the compound from precursor source 22 is introduced into chamber 12 by direct liquid injection. The first predetermined pulse time should be sufficiently long that available binding sites on the substrate surface (coated with metal layers or uncoated) are saturated (i.e., metal-containing compound attached). Typically, the first predetermined pulse time is from 1 second to 20 seconds. The first predetermined pulse time is controlled via control valve 24. At least a portion of the vapor of the titanium metal-containing compound modifies (e.g., adsorbs or reacts with) substrate surface 26 to form the first modified surface. In a refinement, the reaction chamber 12 is then purged with an inert gas for a first purge time. The inert gas is provided from purge gas source 30 and controlled by control valve 32. The first purge time is sufficient to remove the metal-containing compound from the reaction chamber 12 and is typically from 0.5 seconds to 2 minutes. Alternatively, the purging can be replaced with or supplemented by a pumping step. In the next reaction step (step b) of the deposition cycle, the modified surface is contacted with a vapor of the activating compound. The activating compound can be provided from co-reactant source 34, which is controlled by control valve 36. In a refinement, the reaction chamber 12 is then purged with an inert gas for a second purge time as set forth above. The second purge time is sufficient to remove the metal-containing compound from the reaction chamber 12 and is typically from 0.5 seconds to 2 minutes. As set forth above, this purging step can be replaced by or supplemented with a pumping step.

In the next step, the vapor of a metal M′ precursor (i.e., the organometallic precursor includes a metal atom M′) is introduced from precursor source 30 into the reaction chamber 12 for a third predetermined pulse time. In a variation, the compound from precursor source 40 is introduced into chamber 12 by direct liquid injection. The third predetermined pulse time should be sufficiently long that available binding sites on the substrate surface are saturated. Typically, the third predetermined pulse time is from 1 second to 20 seconds. The third predetermined pulse time is controlled via control valve 42. At least a portion of the vapor of the metal M′ precursor modifies (e.g., adsorbs or reacts with) substrate surface 26 to form the second modified surface (step c). In a refinement, the reaction chamber 12 is then purged with an inert gas for a third purge time. The inert gas is provided from purge gas source 30 and controlled by control valve 32. The third purge time is sufficient to remove the metal-containing compound from the reaction chamber 12 and is typically from 0.5 seconds to 2 minutes. Alternatively, the purging can be replaced with or supplemented by a pumping step.

In the next reaction step (step d) of the deposition cycle, the second modified surface is contacted with a vapor of the co-reactant for metal M′. The co-reactant for metal M′ can be provided from co-reactant source 44, which is controlled by control valve 46. In a refinement, the reaction chamber 12 is then purged with an inert gas for a fourth purge time as set forth above. The fourth purge time is sufficient to remove the metal-containing compound from the reaction chamber 12 and is typically from 0.5 seconds to 2 minutes. As set forth above, this purging step can be replaced by or supplemented with a pumping step.

During each deposition cycle, the substrate temperature is typically maintained at a first predetermined temperature for steps a), b), c), and d). In a refinement, the first predetermined temperature is between 200 to 350° C. In a further refinement, steps a) and b) are performed at a first predetermined pressure of about 0.1 millitorrs to 100 Torr.

As set forth above, the deposition cycle (e.g., steps a), b), c) and d)) is repeated a plurality of times to form an alloy coating. For example, the deposition cycle can be repeated 1 to 5000 times. The desired alloy coating thickness depends on the number of deposition cycles. Therefore, in a refinement, the deposition cycle is repeated a plurality of times to form a predetermined thickness of the alloy coating. In a further refinement, the deposition cycle is repeated a plurality of times to form an alloy coating having a thickness from about 5 nanometers to about 200 nanometers. In still another refinement, the deposition cycle is repeated a plurality of times to form an alloy layer having a thickness from about 5 nanometers to about 300 nanometers. In yet another refinement, the deposition cycle is repeated a plurality of times to form an alloy coating having a thickness from about 5 nanometers to about 100 nanometers. In still another refinement, the deposition cycle is repeated a plurality of times to form an alloy coating having a thickness from about 5 nanometers to about 100 nanometers.

In a variation, the method for forming the alloy further includes a step of annealing the titanium-containing alloy layers at a second predetermined temperature for a sufficient time that the titanium-containing alloy layers includes the metal atoms M and metal atoms M′ each independently in the zero oxidation state in an amount greater than 98 mole percent. Annealing can occur after each deposition step or after the deposition has been repeated a plurality of times. Characteristically, the second predetermined temperature is greater than the first predetermined temperature. In a refinement, the second predetermined temperature is greater than in increasing order of preference, 300° C., 310° C., 325° C., or 330° C. Typically, the second predetermined temperature is less than about 400° C.

It should be appreciated that pulse times, purge times, and pump times also depend on the properties of the chemical precursors and the geometric shape of the substrates. Thin film growth on flat substrates uses short pulse and purge times and/or pump times, but pulse and purge times and/or pump times here too in ALD growth on 3-dimensional substrates can be very long. Therefore, in one refinement, pulse times and purge times and/or pump times are each independently from about 0.0001 to 200 seconds. In another refinement, pulse and purge times and/or pump times are each independently from about 0.1 to about 10 seconds.

In another embodiment, a novel organometallic compound having formula 1.2 is provided:

Ti(III)L₃Gₙ (1.2),

wherein:
Ti(III) is a titanium atom in a +3 oxidation state;
G is a neutral ligand;
n is 0, 1, 2, or 3;
L is an anionic ligand selecting from the group consisting of:

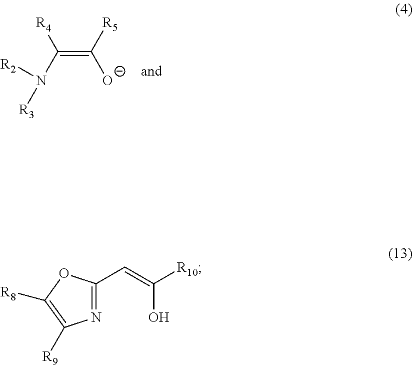

R₂, R₃, R₄, and R₅ are each independently are each independently H, C₁₋₆ alkyl, C₁₋₆ fluorinated alkyl, C₆₋₁₂ aryl, C₂₋₆ heteroaryl, C₅₋₁₂ cycloalkyl, C₂₋₆ heterocycloalkyl, or C₁₋₆ perfluoroalkyl. In a refinement, R₂, R₃, and R₄ are each independently, H, C₁₋₃ alkyl, C₁₋₃ fluorinated alkyl, or C₁₋₃ perfluoroalkyl; and
R₈, R₉, R₁₀ are each independently H, C₁₋₆ alkyl, C₁₋₆ fluorinated alkyl, C₆₋₁₂ aryl, C₂₋₆ heteroaryl, C₅₋₁₂ cycloalkyl, C₂₋₆ heterocycloalkyl, or C₁₋₆ perfluoroalkyl. In a refinement, R₈, R₉, R₁₀ are each independently, H, C₁₋₃ alkyl, C₁₋₃ fluorinated alkyl, or C₁₋₃ perfluoroalkyl.

Specific examples of for L in this embodiment are described by the following formulae:

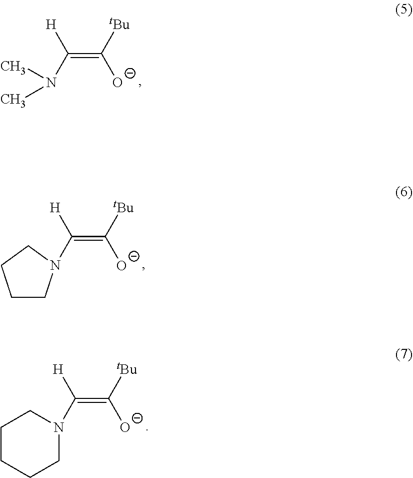

Specific examples of novel organometallic compounds are:

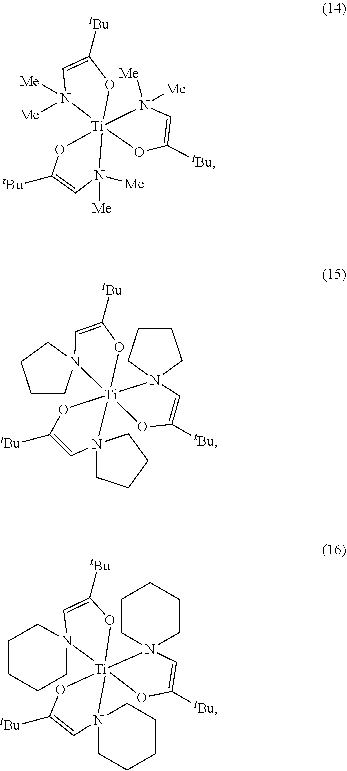

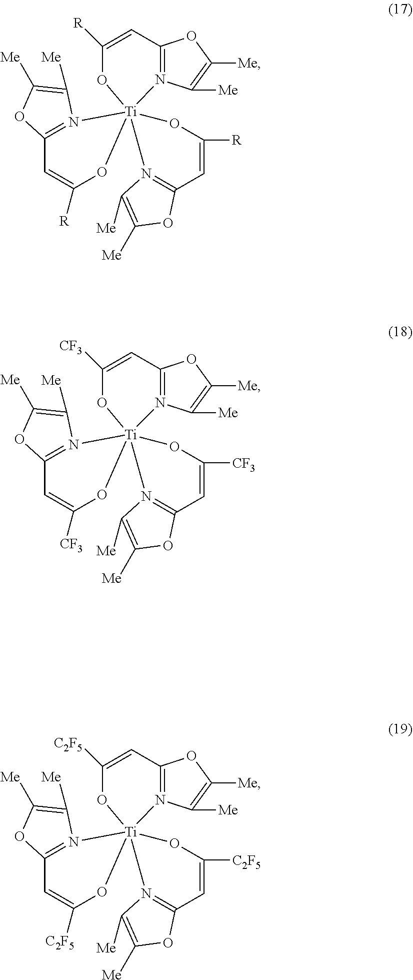

where R is H, C₁₋₆ alkyl, C₁₋₆ fluorinated alkyl, C₆₋₁₂ aryl, C₂₋₆ heteroaryl, C₅₋₁₂ cycloalkyl, C₂₋₆ heterocycloalkyl, or C₁₋₆ perfluoroalkyl.

The following examples illustrate the various embodiments of the present invention. Those skilled in the art will recognize many variations that are within the spirit of the present invention and scope of the claims.

1. Synthesis and Properties of Ti(^{iPr2}DAD)₃

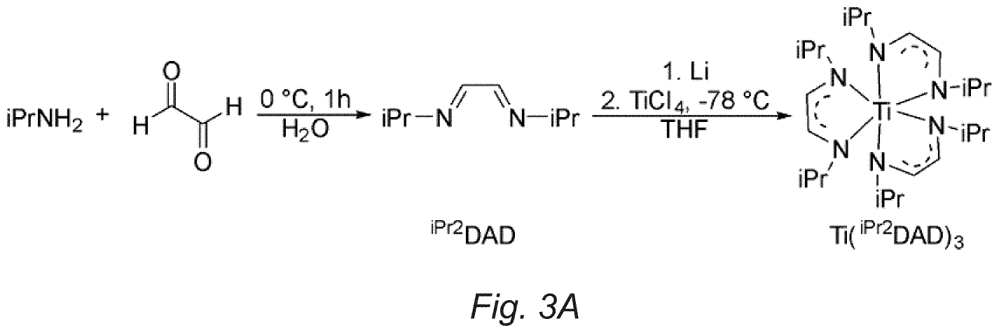

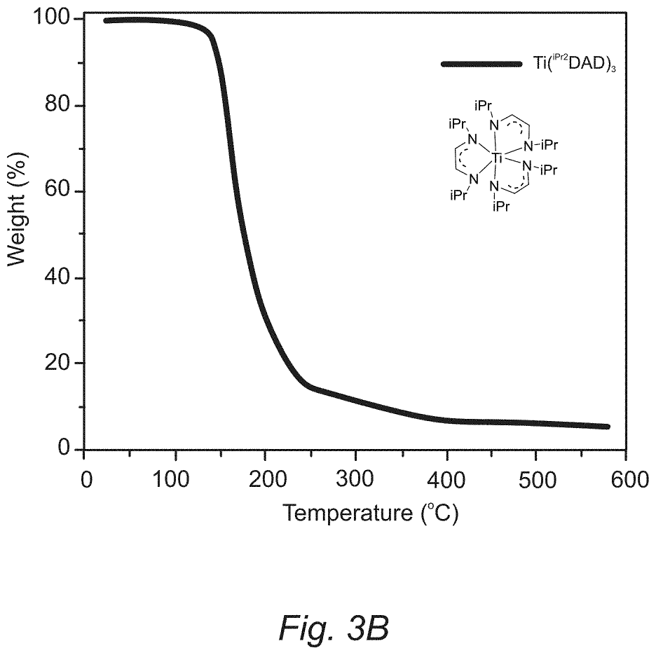

Ti(^{iPr2}DAD)₃ is prepare in accordance to the synthetic scheme depicted in FIG. 3A. FIG. 3B provides plots showing thermogravimetric analysis for Ti(^{iPr2}DAD)₃. Table 1 summarizes the thermal properties for Ti(^{iPr2}DAD)₃.

TABLE 1
Thermal Properties for Ti(^{iPr2}DAD)₃.

| m.p. (° C.) | T_{decomp} (° C.) | T_{sublim.} (° C./0.5 torr) | Residue (%) |
|---|---|---|---|
| 158 | ~250 | 120 | 6.33 |

The thermal experiments revealed a sublimed recovery 94.2% with a residue of about 6% after the heating to 500° C. Ti(^{iBu2}DAD)₃ exhibited similar properties. The thermal decomposition of Ti(^{iPr2}DAD)₃ at about 250° C. and provided a metallic Ti residue. FIG. 3B provides a thermogravimetric analysis for Ti(^{iPr2}DAD)₃.

2. Synthesis of Ti(III) Enaminolate Complexes

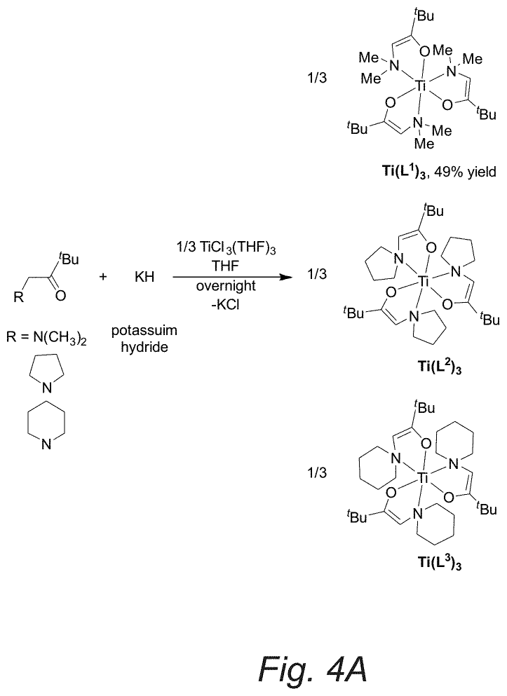

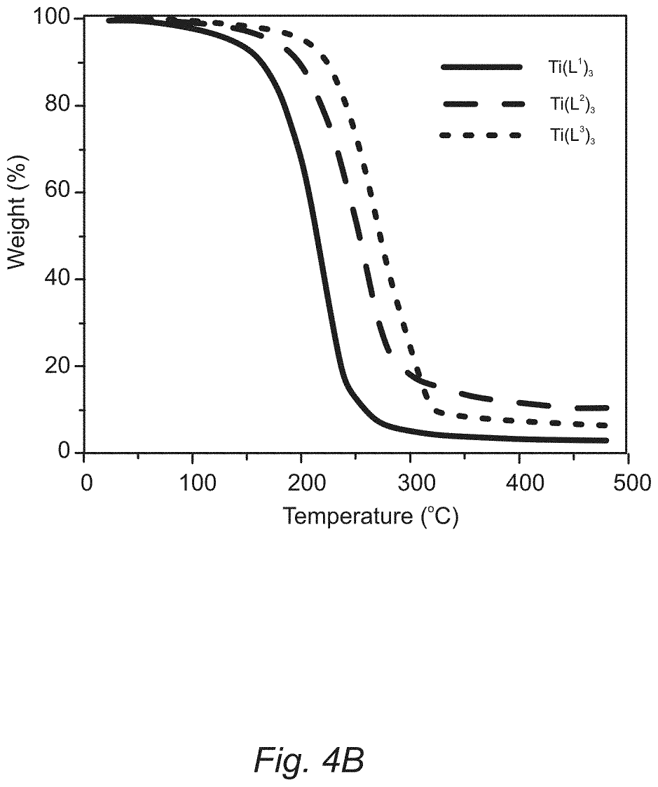

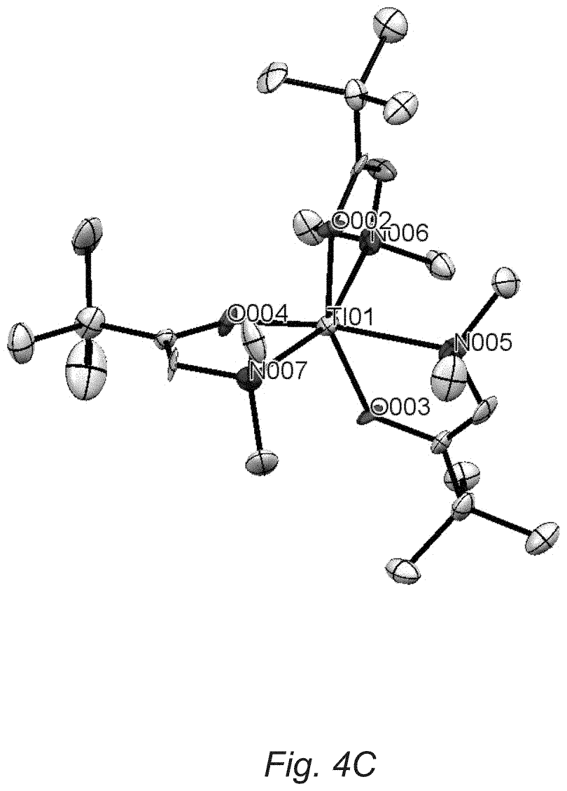

FIG. 4A provides a synthetic scheme for preparing Ti(III) enaminolate complexes. The complexes are prepared by deprotonation of the ligand with KH followed by salt metathesis. After solvent removal, the products were isolated as red/brown crystals by sublimation under reduced pressure. ¹H NMR spectra of the complexes show a broad peak at ˜1.3 ppm, which indicates the formation of paramagnetic Ti(III) complexes. FIG. 4B provides plots showing thermogravimetric analysis for Ti(^{iPr2}DAD)₃ depicted in FIG. 4A. These complexes were monomers by single crystal X-ray analysis. Table 2 provides thermal properties of several Ti(III) enaminolate complexes.

TABLE 2
Thermal Properties of Ti(III) Enaminolate Complexes

| | | | T_{sublim.} | | |
|---|---|---|---|---|---|
| | m.p. | T_{decomp} | (° C./ | Residue | Ti % |
| Ti(L¹)₃ | (° C.) | (° C.) | 0.5 torr) | (%) | by wt |
| Ti(L¹)₃ | 115 | 288 | 95 | 2.8 | 10.1 |
| Ti(L²)₃ | 75 | 262 | 125 | 10.2 | 8.7 |
| Ti(L³)₃ | 172 | 300 | 150 | 6.4 | 8.1 |

The Ti(III) enaminolate complexes are volatile, thermally stable precursors which give metallic residues upon decomposition. From the thermogravimetric analysis provided in FIG. 4B, a temperature window of 135 to 185° C. is observed between sublimation and decomposition making the compounds suitable for ALD with compounds such as ammonia and alkyl amines. Moreover, a metallic silver-colored residues were observed after TGA. FIG. 4B provides the X-ray crystal structure of Ti(L¹)₃. The X-ray structure reveals that Ti is in +3 oxidation state and the compound is monomeric in the solid state.

3. Ti(III) β-Diketonate Complexes

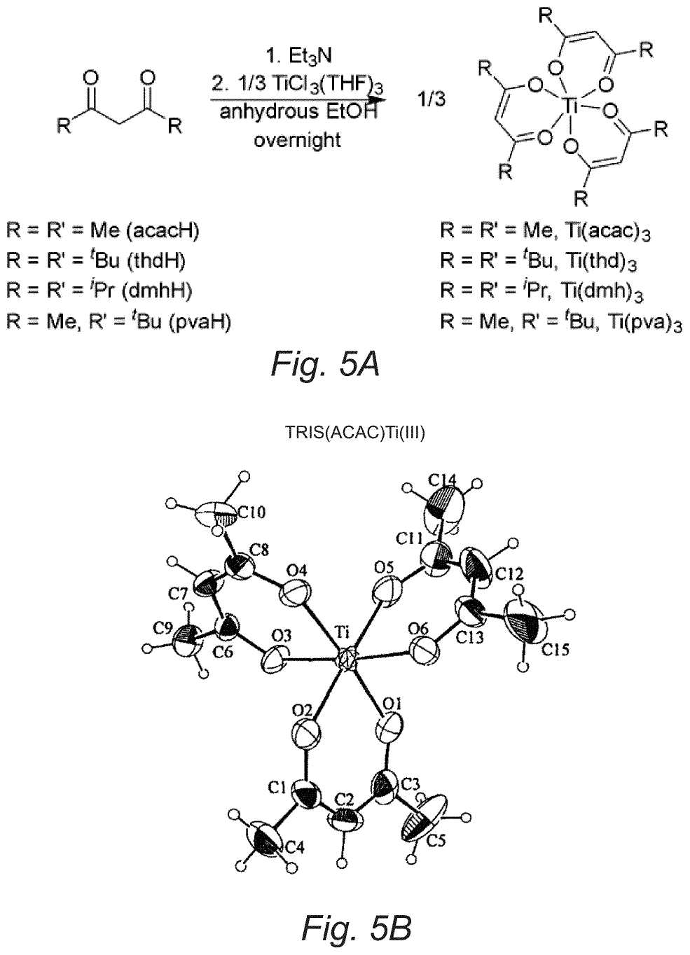

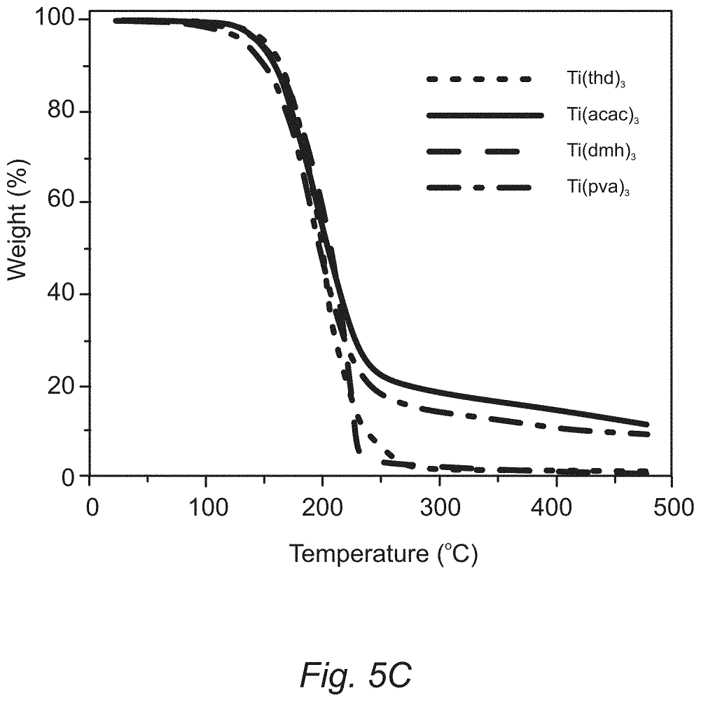

FIG. 5A the provides a synthetic scheme of several Ti(III) β-diketonate complexes. All are previously reported and are monomeric in the solid-state structures. (see, J. Chem. Soc., 1965, 2840-2844; J. Coord. Chem., 1999, 47, 315-318; J. Cryst. Growth 1996, 166, 763-768; J. Mater. Res. 2001, 16, 1838-1849; Integr. Ferroelectr., 1998, 21, 305-318). Ti(thd)₃ has been used in CVD for TiOₓ, SrTiO₃, and BaSrTiO₃. Table 3 provides thermal properties of several Ti(III) β-Diketonate Complexes.

TABLE 3
Thermal Properties of Ti(III) β-Diketonate Complexes

| Ti(III) | m.p. | T_{decomp.} | T_{sublim.} (° C./ | Residue | Ti % |
|---|---|---|---|---|---|
| Complex | (° C.) | (° C.) | 0.5 Torr) | (%) | by wt |
| Ti(acac)₃ | 214 | 220 | 85 | 11.7 | 13.9 |
| Ti(thd)₃ | 250 | 300 | 90 | 1.1 | 8.0 |
| Ti(dmh)₃ | 220 | 285 | 85 | 0.8 | 9.3 |
| Ti(pva)₃ | — | 230 | 85 | 9.59 | 10.15 |

FIG. 5B provides the X-Ray crystal structure of Ti(acac)₃. The X-ray structure reveals that Ti is in +3 oxidation state and the compound is monomeric in the solid state. From the thermogravimetric analysis provided in FIG. 5C, a temperature window of 135 to 210° C. is observed between sublimation and decomposition making the compounds suitable for ALD with compounds such as ammonia and alkyl amines.

4. Synthesis of Ti(III) Fluorinated β-Diketonates

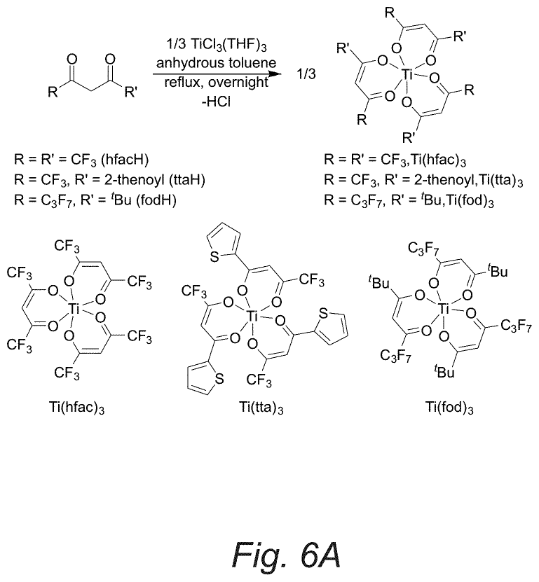

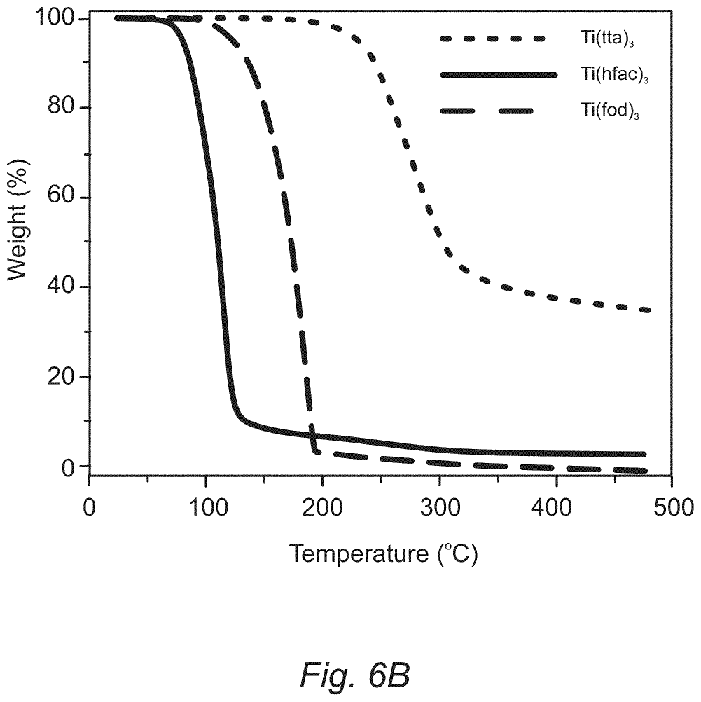

FIG. 6A provides a synthetic scheme for the preparation of Ti(III) fluorinated β-diketonates. The thermal properties for the fluorinated β-diketonates are provided in Table 4.

TABLE 4
Thermal properties of Ti(III) Fluorinated
β-Diketonates Precursor

| Ti(III) | m.p. | T_{decomp.} | T_{sublim.} (° C./ | Residue | Ti % |
|---|---|---|---|---|---|
| Complex | (° C.) | (° C.) | 0.5 Torr) | (%) | by wt |
| Ti(hfac)₃ | 78 | 245 | 89 | 2.48 | 7.15 |
| Ti(tta)₃ | 160 | 242 | 130 | 34.77 | 6.73 |
| Ti(fod)₃ | 88 | 315 | 85 | 0 | 5.13 |

Ti(fod)₃ is observed to have the highest thermal stability. From the thermogravimetric analysis provided in FIG. 6B, each compound is observed to exhibit a wide temperature window between sublimation and decomposition.

5. A New Class of Ti(III) β-Diketonate Complexes

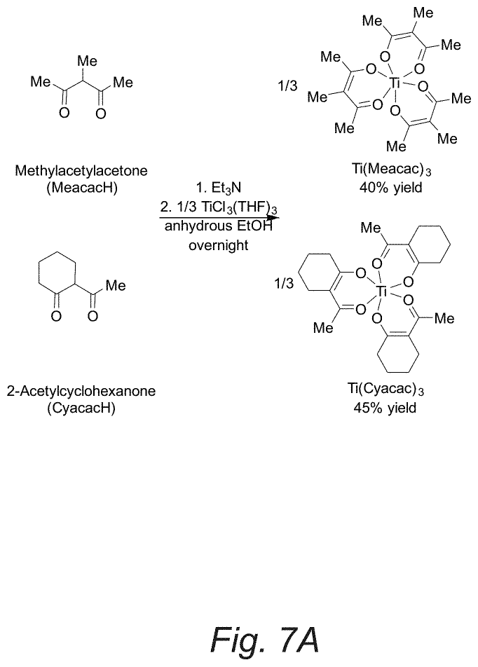

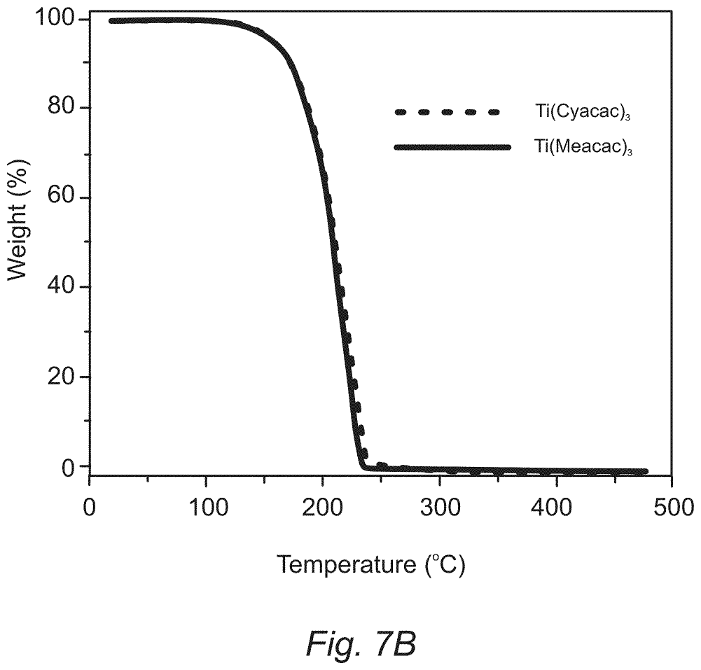

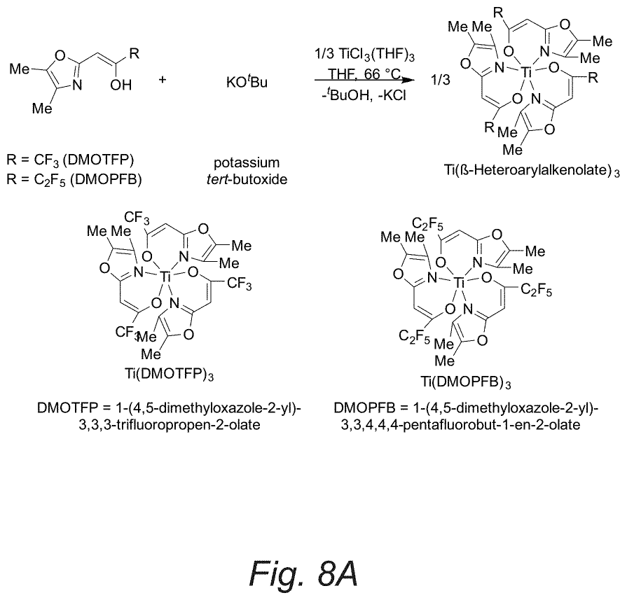

FIG. 7A provides a synthetic scheme for a new class of Ti(III) β-diketonate complexes. The thermal properties for the Ti(III) β-diketonate complexes are provided in Table 5.

TABLE 5
Thermal Properties of Ti(III) β-Diketonate Complexes.

| Ti(III) | m.p. | T_{decomp.} | T_{sublim.} (° C./ | Residue | Ti % |
|---|---|---|---|---|---|
| Complex | (° C.) | (° C.) | 0.5 Torr) | (%) | by wt |
| Ti(Meacac)₃ | 260 | >275 | 120 | 0.82 | 12.36 |
| Ti(Cyacac)₃ | 260 | >273 | 140 | 0.04 | 10.29 |

From the thermogravimetric analysis provided in FIG. 7B, each compound is observed to exhibit a wide temperature window between sublimation and decomposition.

6. β-Heteroarylalkenolate Complexes

The following ligand is used to form a number of complexes:

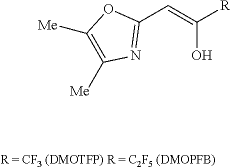

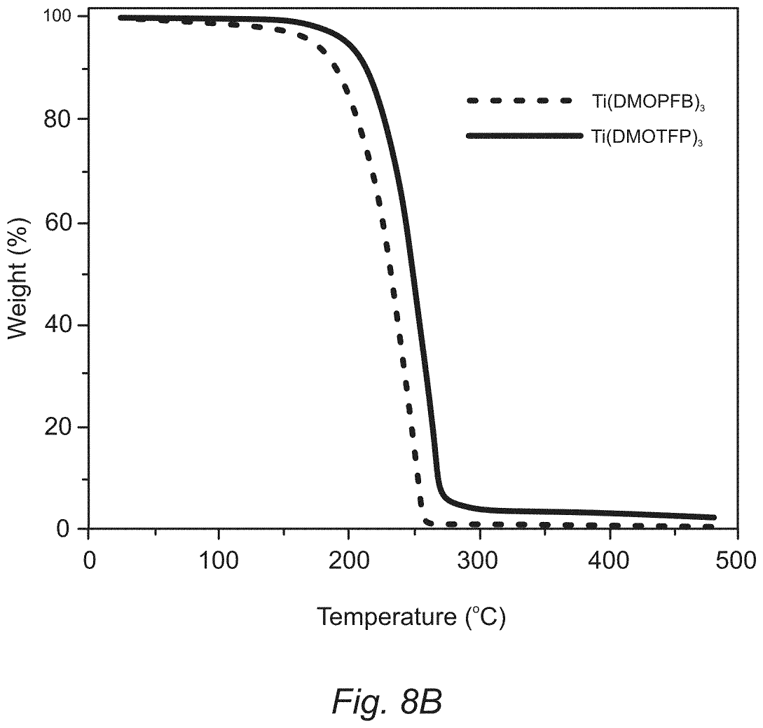

For example, this ligand can be used to form Main group to transitional metals to actinides with different valence states (e.g., Al(DMOTFP)₃, Sn(DMOTFP)₂, Co(DMOTFP)₂, V(DMOTFP)₃, U(DMOPFB)₄). (Inorg. Chem. 2015, 54, 25-37; Inorganica Chim. Acta 2011, 372, 340-346; Dalton Trans. 2017, 46, 12996-13001; Dalton Trans. 2018, 47, 6842-6849; New J. Chem. 2015, 39, 7571-7574) FIG. 8A provides a synthetic scheme for the β-heteroarylalkenolate complexes. The thermal properties for the β-heteroarylalkenolate complexes are provided in Table 6.

TABLE 6
Thermal Properties of β-Heteroarylalkenolate Complexes

| | | | T_{sublim.} | | |
|---|---|---|---|---|---|
| Ti(III) | m.p. | T_{decomp.} | (° C./ | Residue | Ti % |
| Complex | (° C.) | (° C.) | 0.5 Torr) | (%) | by wt |
| Ti(DMOTFP)₃ | 189 | 300 | 150 | 2.37 | 7.18 |
| Ti(DMOPFB)₃ | 146 | 330 | 150 | 0.76 | 5.86 |

Each compound is found to be sufficiently volatile for ALD. From the thermogravimetric analysis provided in FIG. 8B, a wide temperature window between sublimation and decomposition is observed for each compound.

7. Precursor Properties of Ti(BH₄)₃(DME)

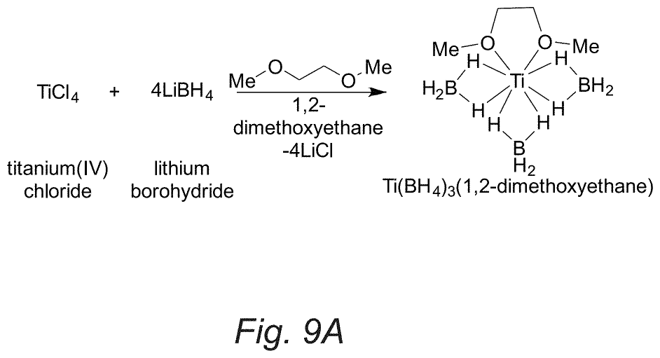

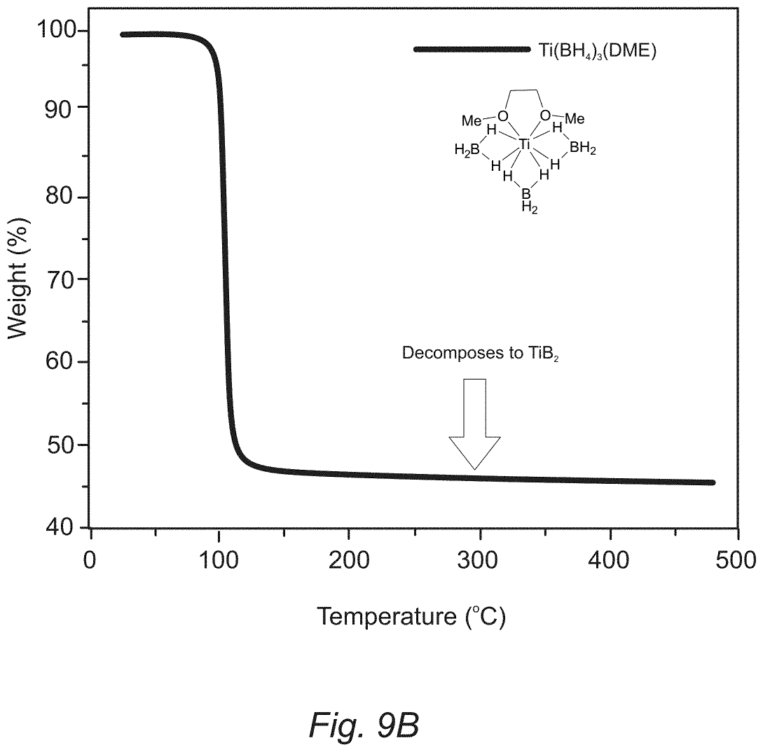

FIG. 9A provides a synthetic scheme for a new class of Ti(BH₄)₃(DME). The thermal properties for Ti(BH₄)₃(DME) are provided in Table 7.

TABLE 7
Thermal Properties of Ti(BH₄)₃(DME)

| | | | T_{sublim.} | | TiB₂ |
|---|---|---|---|---|---|
| Ti(III) | m.p. | T_{decomp.} | (° C./0.5 | Residue | % |
| Complex | (° C.) | (° C.) | Torr) | (%) | by wt |
| Ti(BH₄)₃(DME) | — | 100 | 50 | 45.48 | 44.00 |

Ti(BH₄)₃(DME) is found to be sufficiently volatile for ALD. From the thermogravimetric analysis provided in FIG. 9B, a wide temperature window between sublimation and decomposition is observed for this compound.

8. Synthesis of Ti(BH₄)₃(di-tert-butylethylenediamine)

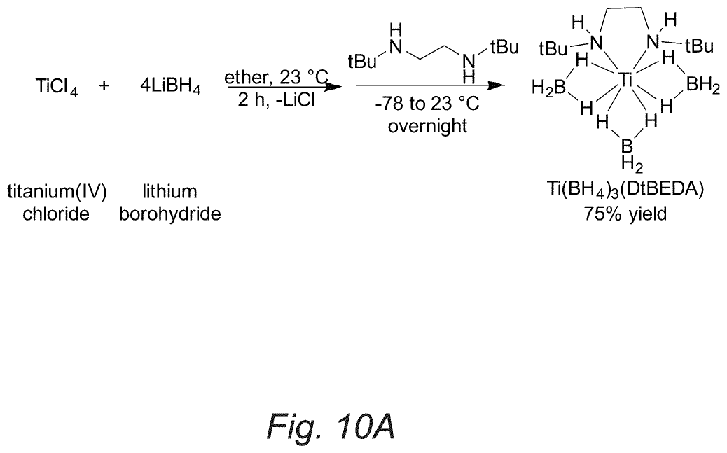

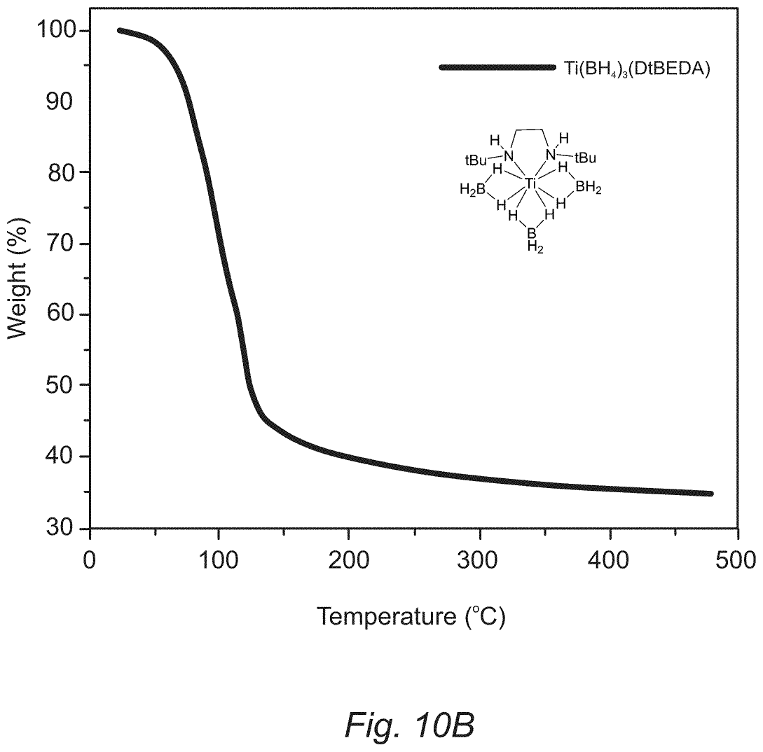

FIG. 10A provides a synthetic scheme Ti(BH₄)₃(di-tert-butylethylenediamine)). LiCl was isolated, followed by the removal of solvent to obtain dark-green (almost black) solids. A colorless liquid, likely di-tert-butylethylenediamine, came out at <100° C. during attempted sublimation. The thermal properties for Ti(BH₄)₃(di-tert-butylethylenediamine)) are provided in Table 8.

TABLE 8
Thermal Properties of Ti(BH₄)₃(Di-tert-butylethylenediamine))

| | | | T_{sublim.} | | TiB₂ |
|---|---|---|---|---|---|
| Ti(III) | m.p. | T_{decomp.} | (° C./0.5 | Residue | % |
| Complex | (° C.) | (° C.) | Torr) | (%) | by wt |
| Ti(BH₄)₃(DME) | — | 100 | — | 34.79 | 44.00 |

9. Synthesis and Purification of Ti(BH₄)₂(Me₂NCH₂CH₂N′Bu)

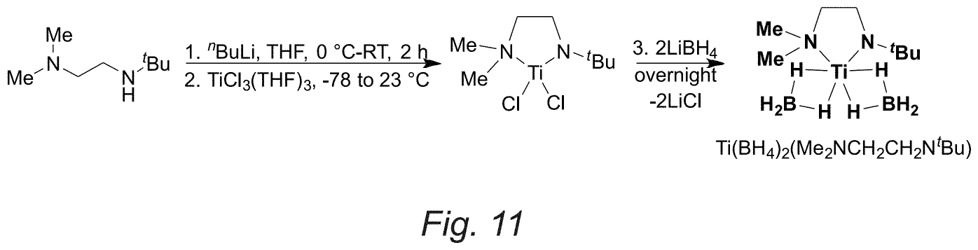

FIG. 11 provides a synthetic scheme Ti(BH₄)₃(Me₂NCH₂CH₂N′Bu). In forming this complex, a chelating amide ligand was employed that was previously used to improve thermal stability in a LAlH₂ precursor (see Chem. Mater. 2018, 30, 1844-1848). The preparation yielded a deep green, hexane-soluble product.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A method for depositing a thin film, the method including a deposition cycle comprising:
a) contacting a surface of a substrate with a vapor of an organometallic compound for a first predetermined pulse time to form a modified surface on the substrate, the organometallic compound being described by formulae 1.1:
M(x)LₘGₙ (1.1),
wherein:
M(x) is a metal in an oxidation state that disproportionates at a temperature above 30° C.;
x is the oxidation state;
L is an anionic ligand;
G is a neutral ligand;
m is 2, 3, 4, or 5; and
n is 0, 1, 2, or 3; and
b) contacting the modified surface with a vapor of an a first co-reactant for a second predetermined pulse time to form metal-containing layer on the surface of the substrate.

2. The method of claim 1 wherein M is Ti(III), Zr(II), Zr(III), Hf(II), Hf(III), V(II), V(III), V(IV), Nb(II), Nb(III), Nb(IV), Ta(II), Ta(III), Ta(IV), Cr(II), Cr(III), Cr(IV), Cr(V), Mo(II), Mo(III), Mo(IV), Mo(V), W(II), W(III), W(IV), or W(V).

3. The method of claim 1 wherein M is Ti(III).

4. The method of claim 1 wherein the a first co-reactant is a reducing agent and the metal-containing layer is a metallic film.

5. The method of claim 4 wherein the reducing agent is selected from the group consisting of molecular hydrogen, atomic hydrogen, silane, disilane, organosilanes, compounds containing Si—H bonds, germane, organogermanes, compounds containing Ge—H bonds, stannane, compounds containing Sn—H bonds, other metal hydride compounds, formic acid, glyoxalic acid, oxalic acid, other carboxylic acids, diborane, compounds containing B—H bonds, hydrazine, carbon-substituted hydrazines, formalin, formaldehyde, organic alcohols, organoaluminum compounds, organozinc compounds, and plasma-activated versions thereof.

6. The method of claim 1 wherein the a first co-reactant is Lewis base and the metal-containing layer is a metallic film.

7. The method of claim 1 wherein the a first co-reactant is an oxidizing agent and the metal-containing layer is a metallic film.

8. The method of claim 7 wherein the oxidizing agent is selected from the group consisting of water, ozone, molecular oxygen, atomic oxygen, organic alcohols, hydrogen peroxide, organic hydroperoxides, organic peroxides, nitrous oxide, and plasma-activated versions of thereof. 6.

9. The method of claim 1 wherein the a first co-reactant is a nitrogen-containing agent and the thin film is a metal nitride.

10. The method of claim 9 wherein the nitrogen-containing agent is selected from the group consisting of ammonia, hydrazine, secondary amines, alkyl-substituted hydrazines, and plasma activated versions thereof.

11. The method of claim 1 wherein L is a bidentate, monoanionic ligand.

12. The method of claim 1 wherein L is selected from the group consisting of tetrahydroborate ligands, dialkyl amide ligands, enaminolate ligands, β-diketonate ligands, and β-heteroarylalkenolate ligands.

13. The method of claim 1 wherein L includes one or more ligands selected from the group consisting of: 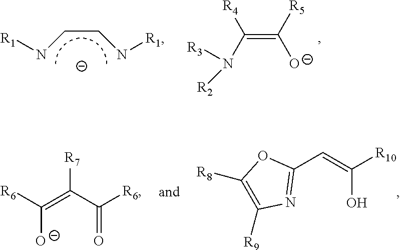
wherein:
R₁ is C₁₋₆ alkyl;
R₂, R₃ are each independently H, C₁₋₆ alkyl, C₁₋₆ fluorinated alkyl, C₆₋₁₂ aryl, C₂₋₆ heteroaryl, C₅₋₁₂ cycloalkyl, C₂₋₆ heterocycloalkyl, or C₁₋₆ perfluoroalkyl or are combined together to form a together to form a C5-7 heterocycloalkyl;
R₄, and R₅ are each independently H, C₁₋₆ alkyl, C₁₋₆ fluorinated alkyl, C₆₋₁₂ aryl, C₂₋₆ heteroaryl, C₅₋₁₂ cycloalkyl, C₂₋₆ heterocycloalkyl, or C₁₋₆ perfluoroalkyl;
R₆, R₇ are each independently H, C₁₋₆ alkyl, C₁₋₆ fluorinated alkyl, C₆₋₁₂ aryl, C₂₋₆ heteroaryl, C5-12 cycloalkyl, C₂₋₆ heterocycloalkyl, or C₁₋₆ perfluoroalkyl; and
R₈, R₉, R₁₀ are each independently, H, C₁₋₆ alkyl, C₁₋₆ fluorinated alkyl, C₆₋₁₂ aryl, C₂₋₆ heteroaryl, C₅₋₁₂ cycloalkyl, C₂₋₆ heterocycloalkyl, or C₁₋₆ perfluoroalkyl.

14. The method of claim 1 wherein L includes one or more ligands selected from the group consisting of:

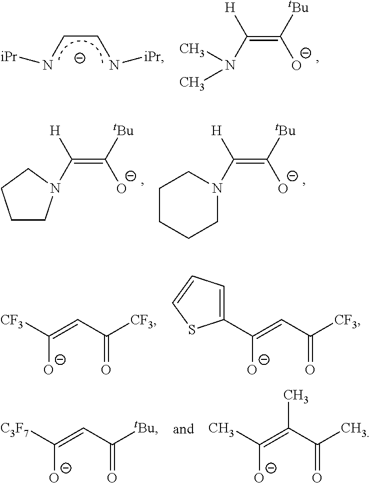

15. The method of claim 1 wherein steps a) and b) are performed at a first predetermined temperature from about 200 to 350° C. and wherein steps a) and b) are performed at a first predetermined pressure of about 0.1 millitorrs to 100 Torr.

16. The method of claim 1 wherein steps a) and b) are repeated a plurality of times in an atomic layer deposition reactor.

17. A method for depositing a metal layer, the method including a deposition cycle comprising:
a) contacting a surface of a substrate with a vapor of a first organometallic compound that includes Ti(III) for a first predetermined pulse time to form a modified surface on the substrate, the first organometallic compound that includes Ti(III) being described by formulae 1.2:
Ti(III)L₃Gₙ (1.2),
wherein:
Ti(III) is a titanium atom in a +3 oxidation state;
L is an anionic ligand;
G is a neutral ligand;
n is 0, 1, 2, or 3; and
b) contacting the modified surface with a vapor of a reducing agent and/or a Lewis base for a second predetermined pulse time to form a titanium metal-containing layer on the substrate.

18. A method for depositing an alloy, the method including a deposition cycle comprising:
a) contacting a surface of a substrate with a vapor of a first metal-containing compound for a first predetermined pulse time to form a first modified surface on the substrate, the first metal-containing compound being described by formulae 1.1:
M(x)LₘGₙ (1.1),
wherein:
M(x) is a metal in an oxidation state that disproportionates at a temperature above 30° C.;
x is the oxidation state;
L is an anionic ligand;
G is a neutral ligand;
m is 2, 3, 4, or 5; and
n is 0, 1, 2, or 3; and
b) contacting the first modified surface with a vapor of a first co-reactant for a second predetermined pulse time to form a metal-containing layer;
c) contacting the metal-containing layer with a vapor of a second organometallic precursor for a third predetermined pulse time to form a second modified surface, wherein the second organometallic precursor includes a metal atom M′ that is different than M; and
c) contacting the second modified surface with a second co-reactant for the second organometallic precursor for a fourth predetermined pulse time to form an M metal-containing layer.

19. The method of claim 18 wherein M is Ti(III), Zr(II), Zr(III), Hf(II), Hf(III), V(II), V(III), V(IV), Nb(II), Nb(III), Nb(IV), Ta(II), Ta(III), Ta(IV), Cr(II), Cr(III), Cr(IV), Cr(V), Mo(II), Mo(III), Mo(IV), Mo(V), W(II), W(III), W(IV), or W(V).

20. The method of claim 18 wherein M is Ti(III).

21. The method of claim 18 wherein M′ is Co, Cr, Mn, Fe, Zn, or Ni.

22. The method of claim 18 wherein co-reactant for the second organometallic precursor is a reducing agent and/or a Lewis base.

23. The method of claim 18 wherein the second organometallic precursor can be described by formula 13:
M′L′ₙ (13)
wherein:
n is 1 to 8;
M′ is a transition metal; and
L′ is a ligand.

24. An organometallic compound having formula 1.2 is provided:
Ti(III)L₃Gₙ (1.2),
wherein:
Ti(III) is a titanium atom in a +3 oxidation state;
G is a neutral ligand;
n is 0, 1, 2, or 3;
L is an anionic ligand selecting from the group consisting of: 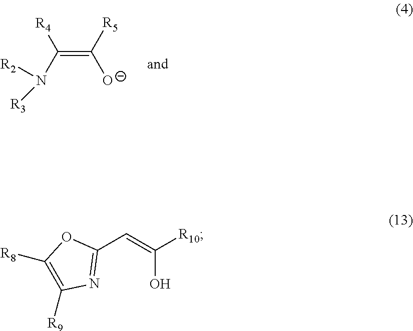
R₂, R₃, R₄, and R₅ are each independently are each independently H, C₁₋₆ alkyl, C₁₋₆ fluorinated alkyl, C₆₋₁₂ aryl, C₂₋₆ heteroaryl, C₅₋₁₂ cycloalkyl, C₂₋₆ heterocycloalkyl, or C₁₋₆ perfluoroalkyl; and
R₈, R₉, R₁₀ are each independently H, C₁₋₆ alkyl, C₁₋₆ fluorinated alkyl, C₆₋₁₂ aryl, C₂₋₆ heteroaryl, C₅₋₁₂ cycloalkyl, C₂₋₆ heterocycloalkyl, or C₁₋₆ perfluoroalkyl.

25. The organometallic compound of claim 24 wherein one or more ligands L are selected from the group consisting of:

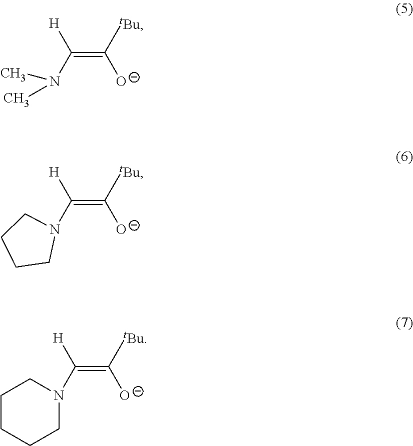

26. The organometallic compound of claim 24 having a formula selected from the group consisting of: 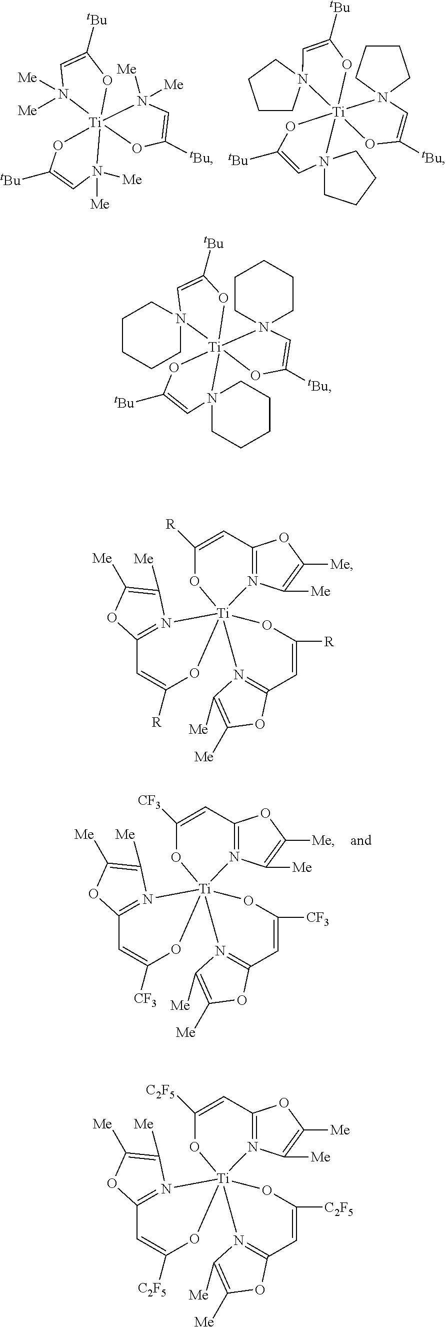
where R is H, C₁₋₆ alkyl, C₁₋₆ fluorinated alkyl, C₆₋₁₂ aryl, C₂₋₆ heteroaryl, C₅₋₁₂ cycloalkyl, C₂₋₆ heterocycloalkyl, or C₁₋₆ perfluoroalkyl.
